(19) United States
(12) Patent Application Publication
(10) Pub. No.: US 2026/0190565 A1
(43) Pub. Date: Jul. 2, 2026

(54) DISPLAY PANEL AND METHOD FOR MANUFACTURING SAME, AND DISPLAY DEVICE

(71) Applicant: BOE TECHNOLOGY GROUP CO., LTD., Beijing (CN)

(72) Inventors: Yingwei LIU, Beijing (CN); Zhonglan ZHAO, Beijing (CN); Zhanfeng CAO, Beijing (CN); Haixu LI, Beijing (CN)

(73) Assignee: BOE TECHNOLOGY GROUP CO., LTD., Beijing (CN)

(21) Appl. No.: 18/729,964

(22) PCT Filed: May 19, 2023
(86) PCT No.: PCT/CN2023/095213

§ 371 Date: Jul. 18, 2024

(51) Int. Cl. H10H 29/39; G02F 1/1333; H10H 29/01; H10H 29/49

(52) U.S. Cl. CPC H10H 29/39; H10H 29/012; H10H 29/49; G02F 1/133342

(57) ABSTRACT

Provide is a display panel. The display panel includes a base; a driving layer disposed on a side of the base, the driving layer including: a first driving structure and a second driving structure; a first light-emitting unit disposed on a side of the base away from the driving layer and a second light-emitting unit disposed on a side of the driving layer away from the base; wherein the first light-emitting unit is electrically connected to the first driving structure, and the second light-emitting unit is electrically connected to the second driving structure; and at least one conductive layer in the first driving structure and at least one conductive layer in the second driving structure are disposed in a same layer.

### CROSS-REFERENCE TO RELATED APPLICATION

This application is a U.S. national stage of international application No. PCT/CN2023/095213, filed on May 19, 2023, the content of which is herein incorporated by reference in its entirety.

### TECHNICAL FIELD

The present disclosure relates to the field of display technology, and in particular, relates to a display panel and a method for manufacturing the same, and a display device.

### BACKGROUND

With the development of display technology, there is usually a demand for double-sided display devices capable of displaying images on both sides of a display.

### SUMMARY

Embodiments of the present disclosure provide a display panel and a method for manufacturing the same, and a display device. The technical solutions are as follows.

According to some embodiments of the present disclosure, a display panel is provided. The display panel includes:
a base;
a driving layer disposed on a side of the base, the driving layer including: a first driving structure and a second driving structure;
a first light-emitting unit disposed on a side of the base away from the driving layer and a second light-emitting unit disposed on a side of the driving layer away from the base;
wherein the first light-emitting unit is electrically connected to the first driving structure, and the second light-emitting unit is electrically connected to the second driving structure; and at least one conductive layer in the first driving structure and at least one conductive layer in the second driving structure are disposed in a same layer.

In some embodiments, the base is provided with a first via, and the display panel further includes: a landing electrode; wherein at least a portion of the landing electrode is disposed in the first via, the landing electrode is electrically connected to the first driving structure, and a side of the landing electrode away from the first driving structure is electrically connected to the first light-emitting unit.

In some embodiments, the side of the base away from the driving layer is provided with a groove in communication with the first via, and the display panel further includes: a first pad disposed in the groove; wherein a side of the first pad is connected to the landing electrode, and a side of the first pad away from the landing electrode is electrically connected to the first light-emitting unit.

In some embodiments, the display panel further includes: a first protective layer disposed in the groove; wherein the first protective layer is distributed between the base and the first pad, and the first protective layer is provided with a second via, and the landing electrode is electrically connected to the first pad through the second via.

In some embodiments, the display panel further includes: a second protective layer disposed on a side of the base facing the driving layer, wherein a portion of the second protective layer extends into the first via and covers at least a portion of an inner wall of the first via;
wherein the portion of the second protective layer extending into the first via is provided with a third via in communication with the second via.

In some embodiments, a side of the first pad away from the driving layer is flush with the side of the base away from the driving layer.

In some embodiments, the first driving structure includes a first transistor, and the second driving structure includes a second transistor; wherein the first transistor includes a first active layer, and the second transistor includes a second active layer, wherein the first active layer and the second active layer are disposed in a same layer.

In some embodiments, the first transistor further includes a first source and a first drain, and the second transistor further includes a second source and a second drain; the first driving structure further includes a first output electrode electrically connected to the first transistor, and the second driving structure further includes a second output electrode electrically connected to the second transistor; wherein
the first source, the first drain, the second source, the second drain, the first output electrode and the second output electrode are disposed in a same layer.

In some embodiments, the first transistor further includes a first gate, wherein the first gate is insulated from the first active layer, the first gate is closer to the base than the first active layer is, the first source and the first drain are lapped with the first active layer, and the first active layer is closer to the base than the first source and the first drain are;
the second transistor further includes a second gate, wherein the second gate is insulated from the second active layer, the second gate is closer to the base than the second active layer is, the second source and the second drain are lapped with the second active layer, and the second active layer is closer to the base than the second source and the second drain are;
the display panel further includes a first adapter electrode, wherein the first adapter electrode, the first gate and the second gate are disposed in a same layer;
wherein the first output electrode is electrically connected to the first light-emitting unit through the first adapter electrode.

In some embodiments, the first transistor further includes a third gate, wherein the third gate is insulated from the first active layer, and the first active layer is closer to the base than the third gate is; the second transistor further includes a fourth gate, wherein the fourth gate is insulated from the second active layer, and the second active layer is closer to the base than the fourth gate is;
the display panel further includes a second adapter electrode, wherein the second adapter electrode, the third gate and the fourth gate are disposed in a same layer;
wherein the first output electrode is electrically connected to the first light-emitting unit through the second adapter electrode and the first adapter electrode in sequence.

In some embodiments, the display panel further includes: an insulating protective layer and a second pad that are disposed on the side of the driving layer away from the base; wherein
the insulating protective layer is provided with a fourth via corresponding to the second pad, at least a portion of the second pad extends into the fourth via and is electrically connected to the second output electrode, and a side of the second pad away from the base is electrically connected to the second light-emitting unit.

In some embodiments, the insulating protective layer includes an organic planarization layer and an inorganic passivation layer that are laminated, wherein the organic planarization layer is closer to the base than the inorganic passivation layer is, the second pad includes a portion outside the fourth via, and the portion of the second pad outside the fourth via is in contact with a side of the inorganic passivation layer away from the base.

In some embodiments, the display panel further includes: a third protective layer disposed on a side of the insulating protective layer away from the base; wherein the second pad includes a portion outside the fourth via, and the third protective layer covers at least a portion of a side surface of the portion of the second pad outside the fourth via.

In some embodiments, a portion of the third protective layer is disposed on the side of the second pad away from the base, and the portion of the third protective layer disposed on the side of the second pad away from the base is provided with a fifth via, wherein an orthographic projection of the fifth via on a plane where the base is disposed is within an orthographic projection of the second pad on the plane where the base is disposed.

In some embodiments, the second pad includes a portion outside the fourth via, wherein a thickness of the portion of the second pad outside the fourth via is greater than or equal to a thickness of the third protective layer.

In some embodiments, the first driving structure further includes a first connection electrode and a second connection electrode, wherein the first connection electrode is disposed in a same layer as the first gate, and the first connection electrode is electrically connected to the first gate, the second connection electrode is disposed in a same layer as the third gate, and the second connection electrode is electrically connected to the third gate, and the first connection electrode is lapped with the second connection electrode;
the second driving structure further includes a third connection electrode and a fourth connection electrode, wherein the third connection electrode is disposed in a same layer as the second gate, the third connection electrode is electrically connected to the second gate, the fourth connection electrode is disposed in a same layer as the fourth gate, and the fourth connection electrode is electrically connected to the fourth gate, and the third connection electrode is lapped with the fourth connection electrode.

In some embodiments, the driving layer includes a first metal layer and a second metal layer that are laminated;
the first driving structure includes a plurality of first driving signal lines disposed in the first metal layer and a second driving signal line disposed in the second metal layer, wherein an extending direction of the first driving signal line intersects with an extending direction of the second driving signal line;
the second driving structure includes a plurality of third driving signal lines disposed in the first metal layer and a fourth driving signal line disposed in the second metal layer, wherein an extending direction of the third driving signal line intersects with an extending direction of the fourth driving signal line;
wherein the extending direction of the first driving signal line is parallel to the extending direction of the third driving signal line, and the extending direction of the second driving signal line is parallel to the extending direction of the fourth driving signal line.

In some embodiments, the plurality of first light-emitting units are arranged in an array in a plurality of rows and a plurality of columns, and the plurality of first driving signal lines include a plurality of groups of first driving signal lines corresponding to the plurality of columns of first light-emitting units, wherein a group of first driving signal lines is electrically connected to each of the first light-emitting units in the corresponding column of first light-emitting units, and one second driving signal line is electrically connected to each of the first light-emitting units in one row of first light-emitting units;
the plurality of second light-emitting units are arranged in an array in a plurality of rows and a plurality of columns, and the plurality of third driving signal lines include a plurality of groups of third driving signal lines corresponding to the plurality of columns of second light-emitting units, wherein a group of third driving signal lines is electrically connected to each of the second light-emitting units in the corresponding column of second light-emitting units, and one fourth driving signal line is electrically connected to each of the second light-emitting units in one row of second light-emitting units;
wherein the plurality of groups of first driving signal lines and the plurality of groups of third driving signal lines are alternately arranged; and the plurality of second driving signal lines and the plurality of fourth driving signal lines are alternately arranged.

In some embodiments, a thickness of the first metal layer is greater than a thickness of the second metal layer.

In some embodiments, the first metal layer includes an electroplating seed layer and a metal layer body that are laminated; wherein the electroplating seed layer is closer to the base than the metal layer body is, and a thickness of the metal layer body is greater than the thickness of the second metal layer.

In some embodiments, the display panel further includes: a first light-absorbing layer disposed on the side of the base away from the driving layer and a second light-absorbing layer disposed on the side of the driving layer away from the base; wherein
the first light-emitting unit is disposed on a side of the first light-absorbing layer away from the base, and the second light-emitting unit is disposed on a side of the second light-absorbing layer away from the base.

In some embodiments, the first light-emitting unit and the second light-emitting unit each include a light-emitting diode.

According to some embodiments of the present disclosure, a method for manufacturing a display panel is provided. The method includes:
forming a driving layer, a first light-emitting unit and a second light-emitting unit on a base;
wherein the driving layer is disposed on a side of the base, and the driving layer includes a first driving structure and a second driving structure; the first light-emitting unit is disposed on a side of the base away from the driving layer and is electrically connected to the first driving structure; the second light-emitting unit is disposed on a side of the driving layer away from the base and is electrically connected to the second driving structure; and at least one conductive layer in the first driving structure and at least one conductive layer in the second driving structure are disposed in a same layer.

In some embodiments forming the driving layer, the first light-emitting unit and the second light-emitting unit on the base includes:
forming a first pad on a rigid substrate;
forming the base on a side of the first pad away from the rigid substrate, wherein the base is provided with a first via;
forming the driving layer on a side of the base away from the rigid substrate, wherein the first driving structure of the driving layer is electrically connected to the first pad through the first via;
stripping the rigid substrate;
transferring the first light-emitting unit to the side of the base away from the driving layer, so that the first light-emitting unit is electrically connected to the first pad; and
transferring the second light-emitting unit to the side of the driving layer away from the base, so that the second light-emitting unit is electrically connected to the second driving structure of the driving layer.

In some embodiments prior to forming the driving layer on the side of the base away from the rigid substrate, the method further includes:
forming a landing electrode electrically connected to the first pad in the first via.

In some embodiments the method further includes:
forming a first protective layer on the rigid substrate on which the first pad is formed prior to forming the base on the side of the first pad away from the rigid substrate, wherein the first protective layer is provided with a second via, and an orthographic projection of the second via on the rigid substrate is within an orthographic projection of the first pad on the rigid substrate; and
forming a second protective layer on the side of the base away from the rigid substrate prior to forming the landing electrode electrically connected to the first pad in the first via, wherein a portion of the second protective layer extends into the first via and covers at least a portion of an inner wall of the first via, and the portion of the second protective layer extending into the first via is provided with a third via in communication with the second via.

In some embodiments the base is made of polyimide, polyvinyl alcohol, polyester, or polyethylene naphthalate.

According to some embodiments of the present disclosure, a display device is provided. The display device includes: a driving component and a display panel electrically connected to the driving component, wherein the display panel is the display panel as described above.

### BRIEF DESCRIPTION OF DRAWINGS

For clearer descriptions of the technical solutions in the embodiments of the present disclosure, the following briefly introduces the accompanying drawings required for describing the embodiments. The accompanying drawings in the following descriptions show merely an embodiment of the present disclosure, and persons of ordinary skill in the art may still derive other drawings from these accompanying drawings without creative effort.

FIG. 1 is a schematic diagram of a film layer structure of a display panel according to some embodiments of the present disclosure;

FIG. 2 is a top view of a display panel from one side according to some embodiments of the present disclosure;

FIG. 3 is a top view of a display panel from another side according to some embodiments of the present disclosure;

FIG. 4 is a schematic diagram of a film layer structure of another display panel according to some embodiments of the present disclosure;

FIG. 5 is a schematic diagram of a film layer structure of still another display panel according to some embodiments of the present disclosure;

FIG. 6 is a top view of a driving layer according to some embodiments of the present disclosure;

FIG. 7 is a schematic diagram of a film layer structure of still another display panel according to some embodiments of the present disclosure;

FIG. 8 is a top view of a driving layer from one side according to some embodiments of the present disclosure;

FIG. 9 is a top view of a driving layer from another side according to some embodiments of the present disclosure;

FIG. 10 is a flowchart of a method for manufacturing a display panel according to some embodiments of the present disclosure;

FIG. 11 is a schematic diagram of forming a sacrificial layer on a side of a rigid substrate according to some embodiments of the present disclosure;

FIG. 12 is a schematic diagram of forming a first pad on a side of a sacrificial layer away from a rigid substrate according to some embodiments of the present disclosure;

FIG. 13 is a schematic diagram of forming a first protective layer on a rigid substrate on which a first pad is formed according to some embodiments of the present disclosure;

FIG. 14 is a schematic diagram of forming a base on a side of a first protective layer away from a rigid substrate according to some embodiments of the present disclosure;

FIG. 15 is a schematic diagram of forming a second protective layer on a side of a base away from a rigid substrate according to some embodiments of the present disclosure;

FIG. 16 is a schematic diagram of forming a landing electrode electrically connected to a first pad in a first via according to some embodiments of the present disclosure;

FIG. 17 is a schematic diagram of forming a driving layer on a rigid substrate on which a landing electrode is formed according to some embodiments of the present disclosure;

FIG. 18 is a schematic diagram of stripping a rigid substrate according to some embodiments of the present disclosure; and

FIG. 19 is a schematic diagram of forming a first light-absorbing layer on a side of a base away from a driving layer and forming a second light-absorbing layer on a side of the driving layer away from the base according to some embodiments of the present disclosure.

### DETAILED DESCRIPTION

To make the objectives, technical solutions and advantages of the present disclosure clearer, the embodiments of the present disclosure will be further described in detail below with reference to the accompanying drawings.

The double-sided display devices are applied to service halls such as airports, train stations, subway stations, canteens and the like with a large flow of people in the communication industry, the government windows, the financial industry, the traffic industry and the window industry, and the double-sided display devices have a wide application prospect.

At present, a double-sided display device generally includes a backlight module and two liquid crystal display panels disposed on two sides of the backlight module. The backlight module can emit light to both sides to provide a light source for the two liquid crystal display panels.

However, the light transmittance of the liquid crystal display panel is generally low, and the backlight module needs to emit light with higher brightness so as to allow the two liquid crystal display panels to present clear display images. As a result, the power consumption of the double-sided display device is high.

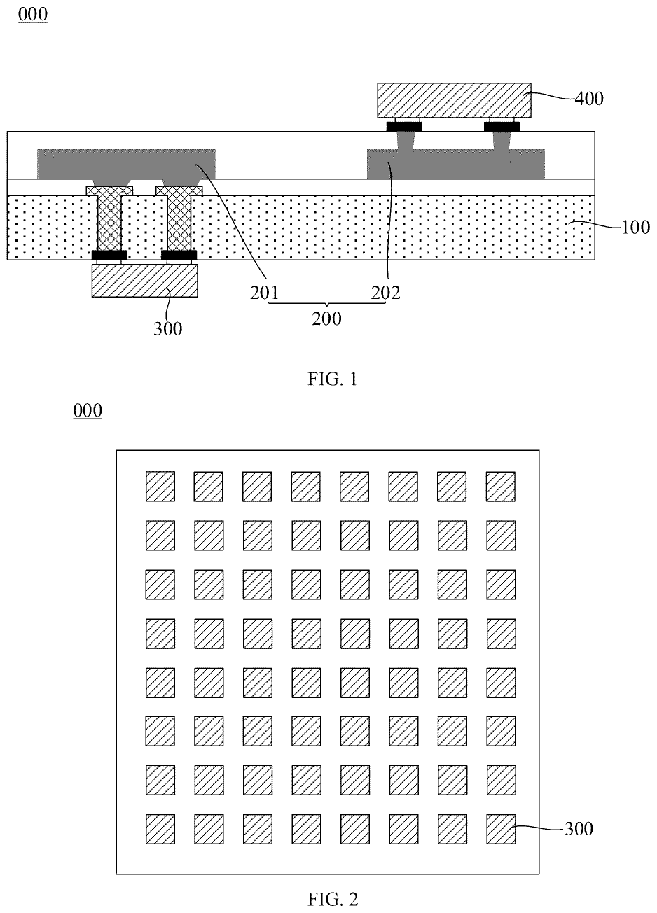

FIG. 1 is a schematic diagram of a film layer structure of a display panel according to some embodiments of the present disclosure. The display panel 000 includes a base 100, a driving layer 200, a first light-emitting unit 300 and a second light-emitting unit 400.

In the display panel 000, the driving layer 200 is disposed on a side of the base 100, and the driving layer 200 includes a first driving structure 201 and a second driving structure 202.

The first light-emitting unit 300 in the display panel 000 is disposed on the side of the base 100 away from the driving layer 200. The first light-emitting unit 300 is electrically connected to the first driving structure 201, and the first driving structure 201 is configured to drive the first light-emitting unit 300 to emit light.

The second light-emitting unit 400 in the display panel 000 is disposed on the side of the driving layer 200 away from the base 100. The second light-emitting unit 400 is electrically connected to the second driving structure 202, and the second driving structure 202 is configured to drive the second light-emitting unit 400 to emit light. In the embodiments of the present disclosure, FIG. 2 is a top view of a display panel from one side according to some embodiments of the present disclosure. Referring to FIG. 2, a plurality of first light-emitting units 300 are provided, the plurality of first light-emitting units 300 are arranged in an array on the side of the base 100 away from the driving layer 200, and each of the first light-emitting units 300 can emit light under the driving of the corresponding first driving structure 201. In this way, by providing a plurality of first light-emitting units 300 arranged in an array on the side of the base 100 away from the driving layer 200, and under the condition that each of the first light-emitting units 300 emits light, a corresponding image can be displayed on the side of the base 100 away from the driving layer 200.

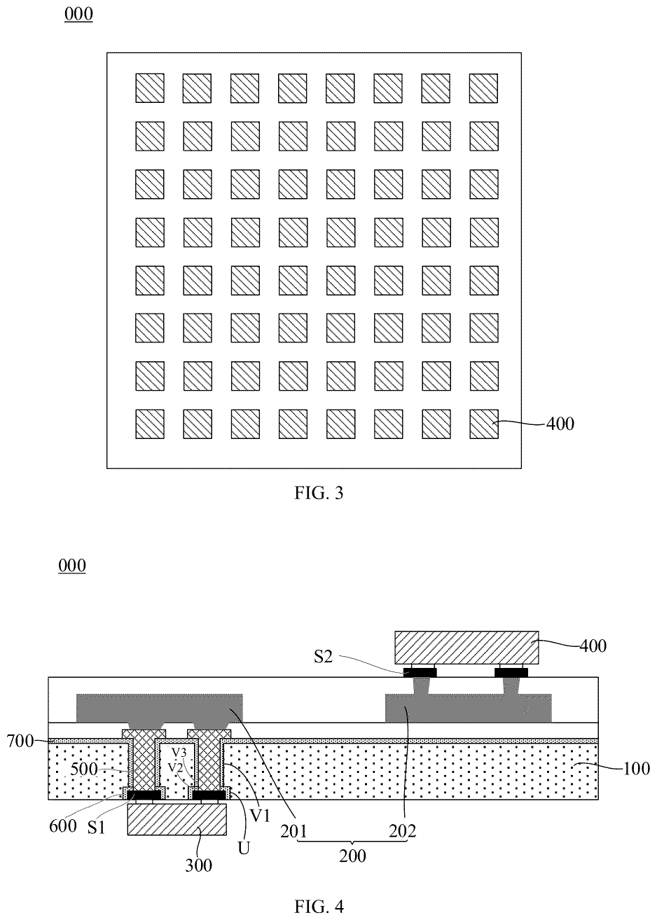

Similarly, FIG. 3 is a top view of a display panel from another side according to some embodiments of the present disclosure. Referring to FIG. 3, a plurality of second light-emitting units 400 are provided, the plurality of second light-emitting units 400 are arranged in an array on the side of the driving layer 200 away from the base 100, and each of the second light-emitting units 400 can emit light under the driving of the corresponding second driving structure 202. In this way, by providing a plurality of second light-emitting units 400 arranged in an array on the side of the driving layer 200 away from the base 100, and under the condition that each of the second light-emitting units 400 emits light, a corresponding image can be displayed on the side of the driving layer 200 away from the base 100.

Therefore, the display panel 000 not only can display images on one side by means of the first light-emitting units 300, but also can display images on the other side by means of the second light-emitting units 400, and the display panel 000 can perform a double-sided display without the backlight module and the two liquid crystal display panels used in combination. In addition, the first driving structure 201 of the driving layer 200 in the display panel 000 can drive the first light-emitting unit 300 to emit light independently, and the second driving structure 202 of the driving layer 200 can drive the second light-emitting unit 400 to emit light independently. Therefore, clear display images can be presented on both sides of the display panel 000 without having to make each light-emitting unit emit light with high brightness. In this way, the power consumption of the display panel 000 can be effectively reduced.

In the present disclosure, the first driving structure 201 of the driving layer 200 includes a plurality of laminated conductive layers, the second driving structure 202 of the driving layer 200 also includes a plurality of laminated conductive layers, and at least one conductive layer in the first driving structure 201 and at least one conductive layer in the second driving structure 202 are disposed in the same layer. In this way, the conductive layer in the first driving structure 201 and the conductive layer in the second driving structure 202 can be simultaneously formed by the same process, which can effectively simplify the manufacturing process of the display panel 000.

In some embodiments, the first light-emitting unit 300 and the second light-emitting unit 400 in the display panel 000 each include: a light-emitting diode (LED). Since the LED has the characteristic of low power consumption, the power consumption of the display panel 000 can be further reduced when the first light-emitting unit 300 and the second light-emitting unit 400 both include LEDs.

The LED is a common size LED, or a mini light-emitting diode (mini LED), or a micro light-emitting Diode (micro LED). It should be noted that, since the micro LED has a relatively small size, when the first light-emitting unit 300 and the second light-emitting unit 400 in the display panel 000 both include micro LEDs, it can be ensured that the display panel 000 has a relatively high resolution on both sides, such that the display panel 000 can display images with good effect on both sides.

In summary, the display panel provided in the embodiments of the present disclosure includes a base, a driving layer, a first light-emitting unit and a second light-emitting unit. A plurality of first light-emitting unit arranged in an array are provided on the side of the base away from the driving layer, and under the condition that each of the first light-emitting units emits light, a corresponding image can be displayed on the side of the base away from the driving layer. A plurality of second light-emitting unit arranged in an array are provided on the side of the driving layer away from the base, and under the condition that each of the second light-emitting units emits light, a corresponding image can be displayed on the side of the driving layer away from the base. Therefore, the display panel not only can display images on one side by means of the first light-emitting units, but also can display images on the other side by means of the second light-emitting units, and the display panel can perform a double-sided display without the backlight module and the two liquid crystal display panels used in combination. In addition, the first driving structure of the driving layer in the display panel can drive the first light-emitting unit to emit light independently, and the second driving structure of the driving layer can drive the second light-emitting unit to emit light independently. Therefore, clear display images can be presented on both sides of the display panel without having to make each light-emitting unit emit light with high brightness. In this way, the power consumption of the display panel can be effectively reduced.

FIG. 4 is a schematic diagram of a film layer structure of another display panel according to some embodiments of the present disclosure. Referring to FIG. 4, the base 100 in the display panel 000 is provided with a first via V1. The display panel 000 further includes a landing electrode 500, and at least a portion of the landing electrode 500 is disposed in the first via V1. In a possible implementation, the landing electrode 500 is totally disposed in the first via V1; and in another possible implementation, a portion of the landing electrode 500 is disposed in the first via V1, and the other portion of the landing electrode 500 is disposed on the side of the base 100 close to the driving layer 200.

The landing electrode 500 is electrically connected to the first driving structure 201 of the driving layer 200, and the side of the landing electrode 500 away from the first driving structure 201 is electrically connected to the first light-emitting unit 300. For example, the portion of the landing electrode 500 disposed in the first via V1 is electrically connected to the first light-emitting unit 300, and the portion of the landing electrode 500 disposed on the side of the base 100 close to the driving layer 200 is electrically connected to the first driving structure 201. In this way, even if the first light-emitting unit 300 is distributed on the side of the base 100 away from the driving layer 200, by forming the first via V1 in the base 100 and providing the landing electrode 500 in the first via V1, the first driving structure 201 of the driving layer 200 can be electrically connected to the first light-emitting unit 300 through the landing electrode 500.

In some embodiments, a groove U communicated with the first via V1 is formed in the side of the base 100 away from the driving layer 200 in the display panel 000. The display panel 000 further includes a first pad S1 disposed in the groove U. One side of the first pad S1 is connected in the groove U to the landing electrode 500 disposed in the first via V1, and the side of the first pad S1 away from the landing electrode 500 is electrically connected to the first light-emitting unit 300. In this case, the first driving structure 201 of the driving layer 200 is electrically connected to the first light-emitting unit 300 through the landing electrode 500 and the first pad S1 in sequence.

For example, the orthographic projection of the first via V1 on the plane where the base 100 is disposed is within the orthographic projection of the groove U on the plane where the base 100 is disposed. Therefore, the orthographic projection of the groove U on the plane where the base 100 is disposed has a larger area, and when the first pad S1 for connecting the landing electrode 500 and the first light-emitting unit 300 is disposed in the groove U, it can be ensured that the orthographic projection of the first pad S1 disposed in the groove U on the plane where the base 100 is disposed has a larger area. For example, the orthographic projection of the portion of the landing electrode 500 disposed in the first via V1 on the plane where the base 100 is disposed is within the orthographic projection of the first pad S1 on the plane where the base 100 is disposed. In addition, since the first light-emitting unit 300 is connected to the first pad S1 in a welding manner, when the orthographic projection of the first pad S1 on the plane where the base 100 is disposed has a larger area, it not only can be ensured that the first light-emitting unit 300 is welded to the first pad S1 more conveniently, but also can be ensured that the welding fastness of the first light-emitting unit 300 and the first pad S1 is high.

It should be noted that the plane where the base 100 is disposed in the embodiment of the present disclosure refers to a plane where the side of the base 100 close to the driving layer 200 is disposed or a plane where the side of the base 100 away from the driving layer 200 is disposed.

In the embodiments of the present disclosure, the display panel 000 further includes a first protective layer 600 disposed in the groove U. The first protective layer 600 is distributed between the base 100 and the first pad S1 in the groove U. In this way, in the manufacturing process of the display panel 000, the first pad S1 is protected by the first protective layer 600 from being corroded by water and oxygen, thereby ensuring that the first pad S1 can be stably welded with the first light-emitting unit 300 subsequently. For example, the first protective layer 600 covers all side surfaces of the first pad S1 to prevent the side surfaces of the first pad S1 from being corroded.

The first protective layer 600 is provided with a second via V2, and the second via V2 is communicated with the first via V1. For example, the orthographic projection of the second via V2 on the plane where the base 100 is disposed is within the orthographic projection of the first via V1 on the plane where the base 100 is disposed. In this way, the landing electrode 500 disposed in the first via V1 can pass through the second via V2 to be electrically connected to the first pad S1.

For example, the second via V2 is in the portion of the first protective layer 600 disposed on the side of the first pad S1 away from the first light-emitting unit 300, and the orthographic projection of the second via V2 on the plane where the base 100 is disposed is within the orthographic projection of the first pad S1 on the plane where the base 100 is disposed, thereby ensuring that the landing electrode 500 is lapped with the side of the first pad S1 away from the first light-emitting unit 300 after passing through the second via V2.

In some embodiments, the display panel 000 further includes a second protective layer 700 disposed on the side of the base 100 facing the driving layer 200. A portion of the second protective layer 700 extends into the first via V1, and the portion of the second protective layer 700 extending into the first via V1 covers at least a portion of an inner wall of the first via V1. For example, the portion of the second protective layer 700 extending into the first via V1 completely covers the inner wall at all positions of the first via V1. In this case, after the water vapor in external environment penetrates into the base 100, the portion of the second protective layer 700 extending into the first via V1 can isolate the water vapor to ensure that the water vapor does not enter the first via V1, thereby ensuring that the landing electrode 500 in the first via V1 is not corroded, and thereby ensuring the stable electrical connection between the first driving structure 201 of the driving layer 200 and the first light-emitting unit 300.

The portion of the second protective layer 700 extending into the first via V1 is provided with a third via V3 communicated with the second via V2. For example, the orthographic projection of the second via V2 on the plane where the base 100 is disposed is completely overlapped with the orthographic projection of the third via V3 on the plane where the base 100 is disposed, that is, the boundary of the orthographic projection of the second via V2 on the plane where the base 100 is disposed coincides with the boundary of the orthographic projection of the third via V3 on the plane where the base 100 is disposed. In this way, the landing electrode 500 disposed in the first via V1 sequentially passes through the third via V3 and the second via V2 to be lapped with the first pad S1.

In some embodiments, the first protective layer 600 and the second protective layer 700 in the display panel 000 are both inorganic protective layers, and are both made of inorganic insulating materials. The inorganic protective layer has a relatively good water-oxygen isolation capability. Therefore, when the first protective layer 600 and the second protective layer 700 are both inorganic protective layers, it can be ensured that both the first protective layer 600 and the second protective layer 700 have good water-oxygen isolation capability, thereby further reducing the probability that the first pad S1 and the landing electrode 500 are corroded.

It should be noted that, in the manufacturing process of the display panel 000, the base 100 in the display panel 000 and the first pad S1 disposed on the side of the base 100 away from the driving layer 200 are both made on a rigid substrate, and the base 100 and the first pad S1 are both in direct contact with the rigid substrate. Therefore, the side of the first pad S1 away from the driving layer 200 is flush with the side of the base 100 away from the driving layer 200. It should also be noted that, before the first light-emitting unit 300 is welded with the first pad S1, the rigid substrate needs to be stripped off, so as to ensure that the first pad S1 can be exposed from the side of the base 100 away from the driving layer 200, thereby ensuring that the first pad S1 can be normally welded with the first light-emitting unit 300.

In the embodiments of the present disclosure, the display panel 000 is further provided with a second pad S2, and the second pad S2 is electrically connected to the second driving structure 202 of the driving layer 200. In this way, the second light-emitting unit 400 can be welded with the second pad S2 so as to be connected to the second driving structure 202. It should be noted that, the driving layer 200 in the display panel 000 may have different structures, and for the driving layers 200 of different structures, the second pads S2 electrically connected to the second driving structures 202 of the driving layers 200 are also arranged differently. The embodiments of the present disclosure are described by taking the following two optional implementations as examples.

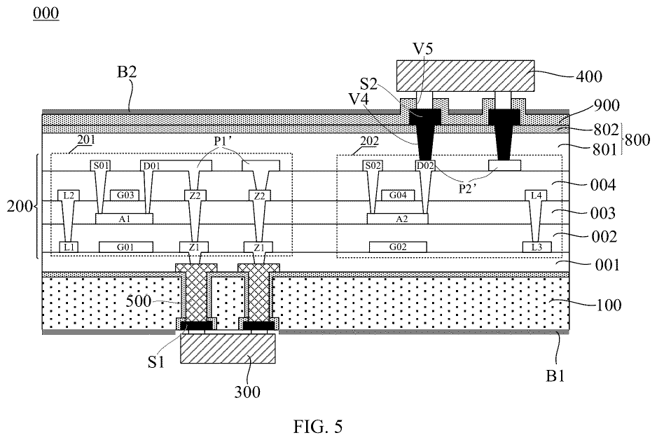

In a first possible implementation, referring to FIG. 5, FIG. 5 is a schematic diagram of a film layer structure of a display panel according to another embodiment of the present disclosure. The driving layer 200 in the display panel 000 is an active driving layer. For example, the first driving structure 201 of the driving layer 200 is a first driving circuit P1. The driving layer 200 includes a plurality of first driving circuits P1, the plurality of first driving circuits P1 are electrically connected to the plurality of first light-emitting units 300 in the display panel 000 in one-to-one correspondence, and each first driving circuit P1 is configured to drive the corresponding first light-emitting unit 300 to emit light. The second driving structure 202 of the driving layer 200 is a second driving circuit P2. The driving layer 200 includes a plurality of second driving circuits P2, the plurality of second driving circuits P2 are electrically connected to the plurality of second light-emitting units 400 in the display panel 000 in one-to-one correspondence, and each second driving circuit P2 is configured to drive the corresponding second light-emitting unit 400 to emit light.

In the present disclosure, the first driving circuit P1 and the second driving circuit P2 in the display panel 000 are disposed in the same layer. That is, the first driving circuit P1 and the second driving circuit P2 are formed by the same process, which can effectively reduce the manufacturing difficulty of the display panel 000.

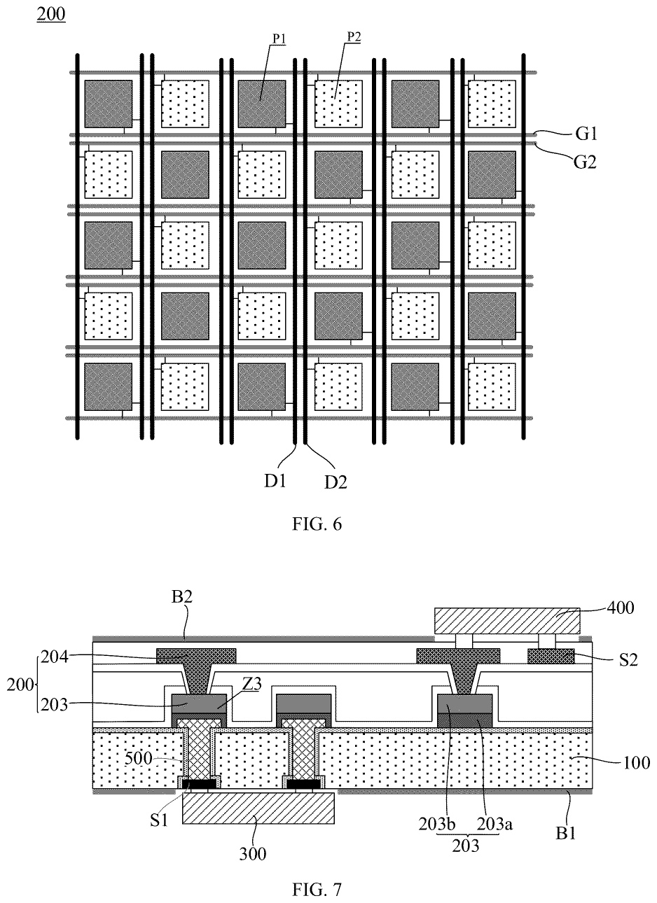

It should be noted that, in order to arrange the plurality of first driving circuits P1 and the plurality of second driving circuits P2 in the display panel 000 uniformly, referring to FIG. 6 which is a top view of a driving layer according to some embodiments of the present disclosure, the plurality of first driving circuits P1 and the plurality of second driving circuits P2 in the display panel 000 are arranged in an array in a plurality of rows and a plurality of columns. In one row of driving circuits, the plurality of first driving circuits P1 and the plurality of second driving circuits P2 are alternately arranged, that is, one second driving circuit P2 is arranged between two adjacent first driving circuits P1, and one first driving circuit P1 is arranged between two adjacent second driving circuits P2. In one column of driving circuits, the plurality of first driving circuits P1 and the plurality of second driving circuits P2 are alternately arranged, that is, one second driving circuit P2 is arranged between two adjacent first driving circuits P1, and one first driving circuit P1 is arranged between two adjacent second driving circuits P2.

The driving layer 200 in the display panel 000 further includes a plurality of first gate lines G1 and a plurality of first data lines D1 that are electrically connected to the plurality of first driving circuits P1, and a plurality of second gate lines G2 and a plurality of second data lines D2 that are electrically connected to the plurality of second driving circuits P2. One first gate line G1 is electrically connected to each first driving circuit P1 in one row of driving circuits, one first data line D1 is electrically connected to each first driving circuit P1 in one column of driving circuits; one second gate line G2 is electrically connected to each second driving circuit P2 in one row of driving circuits, and one second data line D2 is electrically connected to each second driving circuit P2 in one column of driving circuits. The display panel 000 may apply corresponding signals to the first gate lines G1 and the first data lines D1, so that the first driving circuits P1 can normally drive the corresponding first light-emitting units 300 to emit light; and the display panel 000 may also apply corresponding signals to the second gate lines G2 and the second data lines D2, so that the second driving circuits P2 can normally drive the corresponding second light-emitting units 400 to emit light.

In order to ensure that the first gate lines G1 and the first data lines D1 only apply driving signals to the first driving circuits P1 but not to the second driving circuits P2, and ensure that the second gate lines G2 and the second data lines D2 only apply driving signals to the second driving circuits P2 but not to the first driving circuits P1, in a possible case, as shown in FIG. 6, one first gate line G1 and one second gate line G2 are arranged between two adjacent rows of driving circuits, the first gate line G1 is electrically connected to each first driving circuit P1 in one row of the two adjacent rows of driving circuits, and the second gate line G2 is electrically connected to each second driving circuit P2 in the other row of the two adjacent rows of driving circuits; and in addition one first data line D1 and one second data line D2 are arranged between two adjacent columns of driving circuits, the first data line D1 is electrically connected to each first driving circuit P1 in one column of the two adjacent columns of driving circuits, and the second data line D2 is electrically connected to each second driving circuit P2 in the other column of the two adjacent columns of driving circuits. In this case, the plurality of first gate lines G1 and the plurality of second gate lines G2 are alternately arranged, and no interference is generated between the plurality of first gate lines G1 and the plurality of second gate lines G2; and the plurality of first data lines D1 and the plurality of second data lines D2 are also alternately distributed, and no interference is generated between the plurality of first data lines D1 and the plurality of second data lines D2.

In some embodiments, as shown in FIG. 5, the first driving structure 201 (i.e., the first driving circuit P1) includes a first transistor, and the second driving structure 202 (i.e., the second driving circuit P2) includes a second transistor. It should be noted that the first driving circuit P1 includes at least one first transistor, and the first driving circuit P1 can drive the corresponding first light-emitting unit 300 to emit light under the cooperation of the at least one first transistor. Similarly, the second driving circuit P2 includes at least one second transistor, and the second driving circuit P2 can drive the corresponding second light-emitting unit 400 to emit light under the cooperation of the at least one second transistor.

The first transistor in the first driving structure 202a includes a first active layer A1, and the second transistor in the second driving structure 202b includes a second active layer A2. The first active layer A1 and the second active layer A2 are disposed in the same layer and are made of the same material. That is, the first active layer A1 and the second active layer A2 are formed by a single patterning process.

In the present disclosure, the first transistor furthers include a first source S01 and a first drain D01, and the second transistor further includes a second source S02 and a second drain D02. The first source S01 and the first drain D01 in the first transistor are disposed in the same layer and made of the same material as the second source S02 and the second drain DO2 in the second transistor. That is, the first source S01, the first drain D01, the second source S02 and the second drain DO2 are formed by a single patterning process.

In some embodiments, the first driving structure 201 further includes a first output electrode P1′ electrically connected to the first transistor. The first output electrode P1′ of the first driving structure 201 is electrically connected to the first light-emitting unit 300. For example, the first output electrode P1′ of the first driving structure 201 is electrically connected to the first light-emitting unit 300 through the landing electrode 500 and the first pad S1 in sequence. It should be noted that the first driving structure 201 may include two first output electrodes P1′, and the two first output electrodes P1′ are electrically connected to a positive electrode and a negative electrode of the first light-emitting unit 300, respectively. Here, the first output electrode P1′ electrically connected to the first transistor may be understood as that one of the two first output electrodes P1′ is electrically connected to the first transistor, and the other one of the two first output electrodes P1′ is electrically connected to another conductive structure in the first driving structure 201.

The second driving structure 202 further includes a second output electrode P2′ electrically connected to the second transistor. The second output electrode P2′ of the second driving structure 202 is electrically connected to the second light-emitting unit 400. It should be noted that the second driving structure 202 may include two second output electrodes P2′, and the two second output electrodes P2′ are electrically connected to a positive electrode and a negative electrode of the second light-emitting unit 400, respectively. Here, the second output electrode P2′ electrically connected to the second transistor may be understood as that one of the two second output electrodes P2′ is electrically connected to the second transistor, and the other one of the two second output electrodes P2′ is electrically connected to another conductive structure in the second driving structure 202.

The first output electrode P1′, the second output electrode P2′, the first source S01, the first drain D01, the second source S02 and the second drain DO2 are disposed in the same layer and are made of the same material.

It should be noted that the first output electrode P1′ is electrically connected to the first source S01 or the first drain D01 of the first transistor, and the following embodiments are illustratively described by taking an example in which the first output electrode P1′ is electrically connected to the first drain D01. Since the first output electrode P1′ and the first drain D01 are disposed in the same layer, when the first output electrode P1′ is electrically connected to the first drain D01, the first output electrode P1′ is electrically connected to the first drain D01 through the connection electrode disposed in the conductive layer, or the first output electrode P1′ and the first drain D01 are used as the same electrode. It should be further noted that, for the connection manner between the second output electrode P2′ and the second transistor, reference may be made to the connection manner between the first output electrode P1′ and the first transistor, and details are not described herein again.

In the embodiments of the present disclosure, the first transistor further includes a first gate G01. The first gate G01 is insulated from the first active layer A1, and the first gate G01 is closer to the base 100 than the first active layer A1 is. The orthographic projection of the first gate G01 on the plane where the base 000 is disposed is overlapped with the orthographic projection of the first active layer A1 on the plane where the base 000 is disposed. The first source S01 and the first drain D01 of the first transistor are both lapped with the first active layer A1, and the first active layer A1 is closer to the base 100 than the first source S01 and the first drain D01 are.

The second transistor further includes a second gate G02. The second gate G02 is insulated from the second active layer A2, and the second gate G02 is closer to the base 100 than the second active layer A2 is. The orthographic projection of the second gate G02 on the plane where the base 000 is disposed is overlapped with the orthographic projection of the second active layer A2 on the plane where the substrate 000 is disposed. The second source S02 and the second drain D02 of the second transistor are both lapped with the second active layer A2, and the second active layer A2 is closer to the base 100 than the second source S02 and the second drain DO2 are.

The first gate G01 and the second gate G02 are disposed in the same layer and are made of the same material. That is, the first gate G01 and the second gate G02 are formed by a single patterning process.

In the present disclosure, since the first output electrode P1′ of the first driving structure 201 is disposed in the same layer as the first source S01 and the first drain D01 of the first transistor, and the distance between the conductive layer where the first source S01 and the first drain D01 are disposed and the base 100 is large, in order to ensure that the first output electrode P1′ can normally be electrically connected to the first light-emitting unit 300, the display panel 000 further includes a first adapter electrode Z1. The first adapter electrode Z1 and the first gate G01 are disposed in the same layer and made of the same material, that is, the first adapter electrode Z1 and the first gate G01 are formed by a single patterning process. In this way, the first output electrode P1′ of the first driving structure 201 is electrically connected to the first light-emitting unit 300 through the first adapter electrode Z1. For example, the first output electrode P1′ of the first driving structure 201 is electrically connected to the first adapter electrode Z1, and the first adapter electrode Z1 is electrically connected to the first light-emitting unit 300 through the landing electrode 500 and the first pad S1 in sequence. In this way, even if the distance between the first output electrode P1′ of the first driving structure 201 and the landing electrode 500 is large, the first output electrode P1′ of the first driving structure 201 and the landing electrode 500 can be connected by providing the first adapter electrode Z1 therebetween.

In some embodiments, the first transistor further includes a third gate G03. The third gate G03 is insulated from the first active layer A1, and the first active layer A1 is closer to the base 100 than the third gate G03 is. The orthographic projection of the third gate G03 on the plane where the base 100 is disposed is overlapped with the orthographic projection of the first active layer A1 on the plane where the base 100 is disposed, and is overlapped with the orthographic projection of the first gate G01 on the plane where the base 100 is disposed. In a possible implementation, the first gate G01 and the third gate G03 are accessed to different driving signals, so that the first gate G01 and the third gate G03 can control the turn-on and turn-off of the channel region of the first active layer A1. In another possible implementation, the first gate G01 and the third gate G03 are also accessed to the same driving signal. The first gate G01 and the third gate G03 of the first transistor are electrically connected to each other. In this case, the first transistor is a dual-gate transistor, and the first active layer A1 of the first transistor is disposed between the first gate G01 and the third gate G03. In addition, the first gate G01 and the third gate G03 are loaded with the same potential, and the first gate G01 and the third gate G03 are both configured to control the turn-on and turn-off of the channel region of the first active layer A1. In this way, it can be ensured that the first transistor has better electrical performance.

For example, since the first active layer A1 is disposed between the first gate G01 and the third gate G03, in order that the first gate G01 and the third gate G03 can be electrically connected to each other normally, the first driving structure 201 further includes a first connection electrode L1 and a second connection electrode L2. The first connection electrode L1 is disposed in the same layer and made of the same material as the first gate G01, and the first connection electrode L1 is electrically connected to the first gate G01; the second connection electrode L2 is disposed in the same layer and made of the same material as the third gate G03, and the second connection electrode L2 is electrically connected to the third gate G03. The orthographic projection of the first connection electrode L1 on the plane where the base 100 is disposed is not overlapped with the orthographic projection of the first active layer A1 on the plane where the base 100 is disposed, the orthographic projection of the second connection electrode L2 on the plane where the base 100 is disposed is also not overlapped with the orthographic projection of the first active layer A1 on the plane where the base 100 is disposed, and the orthographic projection of the first connection electrode L1 on the plane where the base 100 is disposed is overlapped with the orthographic projection of the second connection electrode L2 on the plane where the base 100 is disposed. Therefore, the second connection electrode L2 is lapped with the first connection electrode L1, so that the first gate G01 and the third gate G03 can be electrically connected to each other.

Similarly, the second transistor further includes a fourth gate G04. The fourth gate G04 is insulated from the second active layer A2, and the second active layer A2 is closer to the base 100 than the fourth gate G04 is. The fourth gate G04 is disposed in the same layer and made of the same material as the third gate G03. That is, the fourth gate G04 and the third gate G03 are formed by a single patterning process. For the effect of the second transistor including the second gate G02 and the fourth gate G04, please refer to the effect of the first transistor including the first gate G01 and the third gate G03, and details are not described herein again.

For example, the second driving structure 202 further includes a third connection electrode L3 and a fourth connection electrode L4. The third connection electrode L3 is disposed in the same layer as the second gate G02, and the third connection electrode L3 is electrically connected to the second gate G02. The fourth connection electrode L4 is disposed in the same layer as the fourth gate G04, and the fourth connection electrode L4 is electrically connected to the fourth gate G04. The third connection electrode L3 is lapped with the fourth connection electrode L4. It should be noted that the principle that the second gate G02 and the fourth gate G04 are electrically connected through the third connection electrode L3 and the fourth connection electrode L4 is the same as the principle that the first gate G01 and the third gate G03 are electrically connected through the first connection electrode L1 and the second connection electrode L2, and details are not described herein again.

In the present disclosure, the display panel 000 further includes a second adapter electrode Z2. The second adapter electrode Z2 is disposed in the same layer and made of the same material as the third gate G03 and the fourth gate G04, that is, the second adapter electrode Z2, the third gate G03 and the fourth gate G04 are formed by a single patterning process. In this way, the first output electrode P1′ of the first driving structure 201 is electrically connected to the first light-emitting unit 300 through the second adapter electrode Z2 and the first adapter electrode Z1 in sequence. For example, the first output electrode P1′ of the first driving structure 201 is electrically connected to the second adapter electrode Z1, and the second adapter electrode Z2 is electrically connected to the first light-emitting unit 300 through the first adapter electrode Z1, the landing electrode 500, and the first pad S1 in sequence. In this way, even if the distance between the first output electrode P1′ of the first driving structure 201 and the landing electrode 500 is large, the first output electrode P1′ of the first driving structure 201 and the landing electrode 500 can be connected by providing the second adapter electrode Z2 and the first adapter electrode Z1 therebetween, which can further improve the stability of the connection between the first output electrode P1′ of the first driving structure 201 and the first light-emitting unit 300.

In the embodiments of the present disclosure, the display panel 000 further includes a buffer layer 001, a first gate insulating layer 002, a second gate insulating layer 003 and an interlayer dielectric layer 004.

The buffer layer 001 is disposed on the side of the landing electrode 500 away from the base 100, and the first conductive layer in the display panel 000 is disposed on the side of the buffer layer 001 away from the base 100. The first conductive layer includes the first gate G01, the second gate G02, the first adapter electrode Z1, the first connection electrode L1 and the third connection electrode L3.

The first gate insulating layer 002 is disposed on the side of the first conductive layer away from the base 100, and the first active layer A1 and the second active layer A2 are both disposed on the side of the first gate insulating layer 002 away from the base 100. Therefore, the first active layer A1 is insulated from the first gate G01 in the first conductive layer by the first gate insulating layer 002, and the second active layer A2 is also insulated from the second gate G02 in the first conductive layer by the first gate insulating layer 002.

The second gate insulating layer 003 is disposed on the side of the first active layer A1 and the side of the second active layer A2 that are away from the base 100, and the second conductive layer in the display panel 000 is disposed on the side of the second gate insulating layer 003 away from the base 100. The second conductive layer includes the third gate G03, the fourth gate G04, the second adapter electrode Z2, the second connection electrode L2 and the fourth connection electrode L4. Therefore, the first active layer A1 is insulated from the third gate G03 in the second conductive layer by the second gate insulating layer 003, and the second active layer A2 is also insulated from the fourth gate G04 in the second conductive layer by the second gate insulating layer 003.

The interlayer dielectric layer 004 is disposed on the side of the second conductive layer away from the base 100, and the third conductive layer in the display panel 000 is disposed on the side of the interlayer dielectric layer 004 away from the base 100. The third conductive layer includes the first source S01, the first drain D01, the second source S02, the second drain DO2, the first output electrode P1′ and the second output electrode P2′.

In the embodiments of the present disclosure, as shown in FIG. 5, the display panel 000 further includes an insulating protective layer 800 disposed on the side of the driving layer 200 away from the base 100. By providing the insulating protective layer 800 on the side of the driving layer 200 away from the base 100, it is ensured that the insulating protective layer 800 can better protect the driving layer 200. The second pad S2 configured to be welded with the second light-emitting unit 400 in the display panel 000 is also disposed on the side of the driving layer 200 away from the base 100. The insulating protective layer 800 is provided with a fourth via V4 corresponding to the second pad S2. At least a portion of the second pad S2 extends into the fourth via V4, and the portion of the second pad S2 extending into the fourth via V4 is connected to the second output electrode P2′ of the second driving structure 202 of the driving layer 200. The side of the second pad S2 away from the base 100 is connected to the second light-emitting unit 400 in a welding manner.

In some embodiments, the insulating protective layer 800 includes an organic planarization layer 801 and an inorganic passivation layer 802 that are laminated. The organic planarization layer 801 is closer to the base 100 than the inorganic passivation layer 802 is. The second pad S2 includes a portion outside the fourth via V4. That is, a portion of the second pad S2 is inside the fourth via V4, the other portion of the second pad S2 is outside the fourth via V4, and the portion of the second pad S2 outside the fourth via V4 is in contact with the side of the inorganic passivation layer 802 away from the base 100.

Here, in the case that the organic planarization layer 801 is provided on the side of the driving layer 200 away from the base 100, it can be ensured that the side of the organic planarization layer 801 away from the base 100 has good flatness, thereby ensuring the good stability of the film layer structure disposed on the side of the organic planarization layer 801 away from the base. In addition, in order to ensure the stable electrical connection between the second output electrode P2′ of the second driving structure 202 and the second light-emitting unit 400, the second pad S2 needs to be made of a metal material with good conductivity, for example, the second pad S2 is made of copper. However, if the metal material with good conductivity is directly prepared on the organic planarization layer 801, the metal material with good conductivity is easily separated from the organic planarization layer 801. Therefore, the inorganic passivation layer 802 is first formed on the side of the organic planarization layer 801 away from the base 100, and then the metal material with good conductivity is prepared on the side of inorganic passivation layer 802 away from the base 100. In this way, it can be ensured that the second pad S2 made of the metal material with good conductivity is not easily separated from the inorganic passivation layer 802, and thus the second pad S2 can be stably disposed on the insulating protective layer 800.

In the embodiments of the present disclosure, the display panel 000 further includes a third protective layer 900 disposed on the side of the insulating protective layer 800 away from the base 100. The third protective layer 900 covers at least a part of the side surface of the portion of the second pad S2 outside the fourth via V4. For example, the third protective layer 900 completely covers the side surface at all positions of the portion of the second pad S2 outside the fourth via V4. In this case, the third protective layer 900 can prevent the water and oxygen in external environment from eroding the second pad S2 from the side surface of the second pad S2, thereby reducing the probability that the second pad S2 is corroded, and ensuring the stable electrical connection between the second output electrode P2′ of the second driving structure 202 and the second light-emitting unit 400. In some embodiments, the third protective layer 900 in the display panel 000 is made of an inorganic material with a relatively good water-oxygen isolation capability, that is, the third protective layer 900 belongs to an inorganic protective layer, which can further reduce the probability that the second pad S2 is corroded.

In the present disclosure, a portion of the third protective layer 900 is disposed on the side of the second pad S2 away from the base 100, and the portion of the third protective layer 900 disposed on the side of the second pad S2 away from the base 100 is provided with a fifth via V5. The orthographic projection of the fifth via V5 on the plane where the base 100 is disposed is within the orthographic projection of the second pad S2 on the plane where the base 100 is disposed. In this way, the second light-emitting unit 400 is welded to the second pad S2 through the fifth via V5.

It should be noted that the boundary of the orthographic projection of the fifth via V5 on the plane where the base 100 is disposed does not coincide with the boundary of the orthographic projection of the second pad S2 on the plane where the base 100 is disposed. In this way, it can be ensured that the third protective layer 900 can not only completely cover the side surface at all positions of the second pad S2 but also can partially cover the edge region of the second pad S2 away from the base 100, thereby further reducing the probability that the second pad S2 is corroded.

In some embodiments, the thickness of the portion of the second pad S2 outside the fourth via V4 is greater than or equal to the thickness of the third protective layer 900. The thickness of the portion of the second pad S2 outside the fourth via V4 refers to the distance between the side of the second pad S2 away from the base 100 and the side of the third protective layer 900 away from the base 100. In this way, it can be ensured that the portion of the second pad S2 outside the fourth via V4 is relatively thick, and thus the second pad S2 has a small resistance, so that the second pad S2 has a better conductive capability.

It should be noted that, since the portion of the second pad S2 outside the fourth via V4 is relatively thick, and the third protective layer 900 belongs to an inorganic protective layer, the side of the second pad S2 away from the base 100 protrudes from the side, away from the base 100, of the portion of the third protective layer 900 that is in contact with the insulating protective layer 800. It should also be noted that, although the second pad S2 has a protruding portion on a side of the display panel 000, the second pad S2 can still be welded to the second light-emitting unit 400. Therefore, the protruding portion does not need to be leveled by an additional process on the side of the display panel 000, which can effectively simplify the manufacturing difficulty of the display panel 000.

In a second optional implementation, referring to FIG. 7, FIG. 7 is a schematic diagram of a film layer structure of another display panel according to another embodiment of the present disclosure. The driving layer 200 in the display panel 000 is a passive driving layer. For example, the driving layer 200 includes a first metal layer 203 and a second metal layer 204 that are laminated. The first metal layer 203 is closer to the base 100 than the second metal layer 204 is.

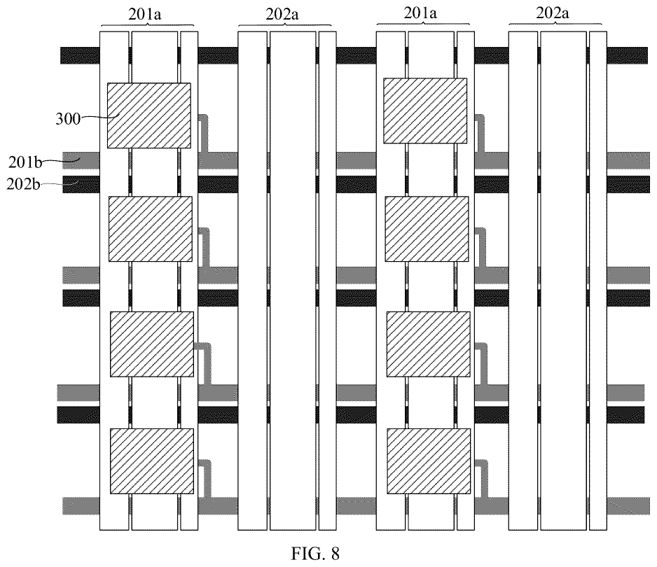

For a clearer view of the structure of the first driving structure 201 of the driving layer 200 in the display panel 000, please refer to FIG. 8, and FIG. 8 is a top view of the driving layer on one side according to some embodiments of the present disclosure. The first driving structure 201 of the driving layer 200 includes a plurality of first driving signal lines 201a disposed in the first metal layer 203 and a second driving signal line 201b disposed in the second metal layer 204. The extending direction of the first driving signal line 201a intersects with the extending direction of the second driving signal line 201b. For example, the extending direction of the first driving signal line 201a is perpendicular to the extending direction of the second driving signal line 201b. Both the first driving signal line 201a and the second driving signal line 201b are electrically connected to the first pad S1 through the landing electrode 500. In this way, after the first light-emitting unit 300 is welded to the first pad S1, the first light-emitting unit 300 is driven to emit light under the cooperation of the first driving signal line 201a and the second driving signal line 201b.

It should be noted that the first driving signal line 201a belongs to a portion of the first metal layer 203, the second driving signal line 201b belongs to a portion of the second metal layer 204, and the first metal layer 203 is closer to the base 100 than the second metal layer 204 is. Therefore, the first driving signal line 201a can be directly electrically connected to the first pad S1 through the landing electrode 500. For the electrical connection between the second driving signal line 201b and the first pad S1, a third adapter electrode Z3 for connecting the second driving signal line 201b and the landing electrode 500 is disposed in the first metal layer 203, and the second driving signal line 201b is electrically connected to the first pad S1 through the third adapter electrode Z3 and the landing electrode 500 in sequence.

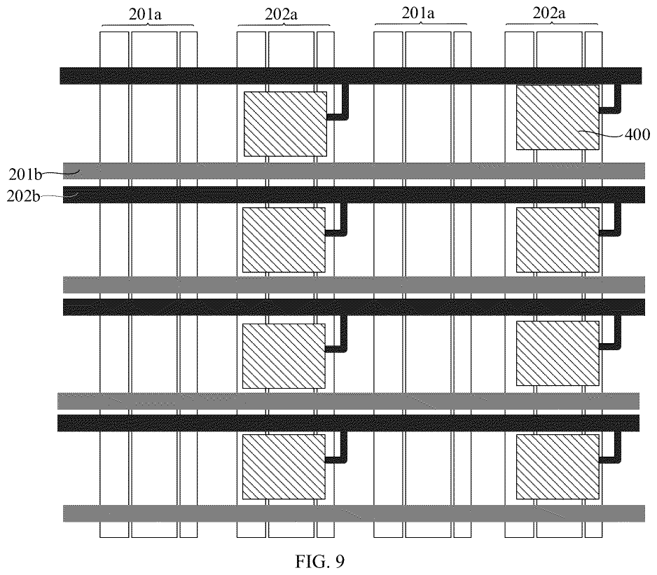

For a clearer view of the structure of the second driving structure 202 of the driving layer 200 in the display panel 000, please refer to FIG. 9, and FIG. 9 is a top view of the driving layer on another side according to some embodiments of the present disclosure. The second driving structure 202 of the driving layer 200 includes a plurality of third driving signal lines 202a disposed in the first metal layer 203 and a fourth driving signal line 202b disposed in the second metal layer 204. The extending direction of the third driving signal line 202a intersects with the extending direction of the fourth driving signal line 202b. For example, the extending direction of the third driving signal line 202a is perpendicular to the extending direction of the fourth driving signal line 202b. Both the third driving signal line 202a and the fourth driving signal line 202b are electrically connected to the second pad S2. In this way, after the second light-emitting unit 400 is welded to the second pad S2, the second light-emitting unit 400 can be driven to emit light under the cooperation of the third driving signal line 202a and the fourth driving signal line 202b.

It should be noted that the third driving signal line 202a belongs to a portion of the first metal layer 203, the fourth driving signal line 202b belongs to a portion of the second metal layer 204, and the first metal layer 203 is closer to the base 100 than the second metal layer 204 is. Therefore, the second pad S2 belongs to a portion of the second metal layer 204, and the fourth driving signal line 202b is directly electrically connected to the second pad S2. For the electrical connection between the third driving signal line 202a and the second pad S2, an adapter via V0 is formed in the display panel 000, and the third driving signal line 202a is electrically connected to the second pad S2 through the adapter via V0.

In the present disclosure, the first driving signal line 201a and the third driving signal line 202a are disposed in the same layer and made of the same material, and both belong to portions of the first metal layer 203. In order to ensure that no short circuit occurs between the first driving signal line 201a and the third driving signal line 202a, the extending direction of the first driving signal line 201a is parallel to the extending direction of the third driving signal line 202a. Similarly, the second driving signal line 201b and the fourth driving signal line 202b are disposed in the same layer and made of the same material, and both belong to portions of the second metal layer 204. In order to ensure that no short circuit occurs between the second driving signal line 201b and the fourth driving signal line 202b, the extending direction of the second driving signal line 201b is parallel to the extending direction of the fourth driving signal line 202b.

In some embodiments, as shown in FIG. 8, the plurality of first light-emitting units 300 in the display panel 000 are arranged in an array in a plurality of rows and a plurality of columns. The plurality of first driving signal lines 201a in the first metal layer 203 include a plurality of groups of first driving signal lines 201a corresponding to the plurality of columns of first light-emitting units 300, a group of first driving signal lines 201a is electrically connected to each first light-emitting unit 300 in the corresponding column of first light-emitting units 300, and one second driving signal line 201b is electrically connected to each first light-emitting unit 300 in one row of first light-emitting units 300. Here, a group of first driving signal lines 201a electrically connected to one column of first light-emitting units 300 includes an anode driving signal line or a cathode driving signal line, a data signal line, and a ground line, and one second driving signal line 201b electrically connected to one row of first light-emitting units 300 is a power signal line.

As shown in FIG. 9, the plurality of second light-emitting units 400 in the display panel 000 are arranged in an array in a plurality of rows and a plurality of columns. The plurality of third driving signal lines 202a in the first metal layer 203 include a plurality of groups of third driving signal lines 202a corresponding to the plurality of columns of second light-emitting units 400, a group of third driving signal lines 202a is electrically connected to each second light-emitting unit 400 in the corresponding column of second light-emitting units 400, and one fourth driving signal line 202b is electrically connected to each second light-emitting unit 400 in one row of second light-emitting units 400. Here, a group of third driving signal lines 202a electrically connected to one column of second light-emitting units 400 includes an anode driving signal line or a cathode driving signal line, a data signal line, and a ground line, and one fourth driving signal line 202b electrically connected to one row of second light-emitting units 400 is a power signal line.

The plurality of groups of first driving signal lines 201a and the plurality of groups of third driving signal lines 202a are alternately arranged. That is, one group of third driving signal lines 202a is distributed between the two adjacent groups of first driving signal lines 201a, and one group of first driving signal lines 201a is distributed between two adjacent groups of third driving signal lines 202a. The plurality of second driving signal lines 201b and the plurality of fourth driving signal lines 202b are alternately arranged. That is, one fourth driving signal line 202b is distributed between two adjacent second driving signal lines 201b, and one second driving signal line 201b is distributed between two adjacent fourth driving signal lines 202b. In this way, even if the first driving signal line 201a and the third driving signal line 202a are portions of the first metal layer 203, and the second driving signal line 201b and the fourth driving signal line 202b are portions of the second metal layer 204, it can be ensured that mutual interference is not generated between the first driving signal line 201a and the third driving signal line 202a, and mutual interference is not generated between the second driving signal line 201b and the fourth driving signal line 202b, and it can be ensured that the first light-emitting unit 300 is driven to emit light under the cooperation of the first driving signal line 201a and the second driving signal line 201b, and the second light-emitting unit 400 is driven to emit light under the cooperation of the third driving signal line 202a and the fourth driving signal line 202b.

It should be noted that, when the driving layer 200 is a passive driving layer, the display panel 000 generally further includes a plurality of first chips (not marked in the figure) and a plurality of second chips (not marked in the figure). The plurality of first chips correspond to the plurality of first light-emitting units 300, and the first chip is welded to the first pad S1. In this way, the first chip is controlled to work under the cooperation of the first driving signal line 201a and the second driving signal line 201b, so that the first chip can send a corresponding driving signal to the corresponding first light-emitting unit 300 to control the first light-emitting unit 300 to emit light. Similarly, the plurality of second chips correspond to the plurality of second light-emitting units 400, and the second chip is also welded to the second pad S2. In this way, the second chip is controlled to work under the cooperation of the third driving signal line 202a and the fourth driving signal line 202b, so that the second chip can send a corresponding driving signal to the corresponding second light-emitting unit 400 to control the second light-emitting unit 400 to emit light.

In some embodiments, the thickness of the first metal layer 203 is greater than the thickness of the second metal layer 204. The thickness of the first metal layer 203 and the thickness of the second metal layer 204 each refer to the thickness of the portion of the metal layer that is disposed above the insulating layer. Since the driving signal lines in the first metal layer 203 include an anode driving signal line or a cathode driving signal line, a data signal line and a ground line, and the anode driving signal line or the cathode driving signal line and the ground line are loaded with signals of a fixed potential, in order to ensure that the potential is consistent at various positions of the anode driving signal line or the cathode driving signal line and the ground line, the resistances of the anode driving signal line or the cathode driving signal line and the ground line need to be reduced. In the case that the thickness of the first metal layer 203 is large, it can be ensured that the resistances of the anode driving signal line or the cathode driving signal line and the ground line in the first metal layer 203 are small.

For example, the first metal layer 203 includes an electroplating seed layer 203a and a metal layer body 203b that are laminated. The electroplating seed layer 203a is closer to the base 100 than the metal layer body 203b is, and the thickness of the metal layer body 203b is greater than the thickness of the second metal layer 204. During the manufacture of the first metal layer 203, the electroplating seed layer 203a is formed on the base 100 first, and then the metal layer body 203b having a larger thickness is formed on the side of the electroplating seed layer 203a away from the base 100 by an electroplating process.

It should be noted that, for the display panel in the second optional implementation, an insulating layer is provided between the first metal layer 203 and the second metal layer 204 in the display panel 000, and an insulating layer is also provided on the side of the second metal layer 204 away from the base 100. For structures of these insulating layers, please refer to corresponding content in the related art, and details are not described herein again.

In some embodiments, as shown in FIG. 5 and FIG. 7, the display panel 000 further includes a first light-absorbing layer B1 disposed on the side of the base 100 away from the driving layer 200 and a second light-absorbing layer B2 disposed on the side of the driving layer 200 away from the base 100. The first light-emitting unit 300 is disposed on the side of the first light-absorbing layer B1 away from the base 100, and the second light-emitting unit 400 is disposed on the side of the second light-absorbing layer B2 away from the base 100. In this case, part of the light emitted from the first light-emitting unit 300 is blocked by the first light-absorbing layer B1, so that the light emitted from the first light-emitting unit 300 is not emitted out from a side of the second light-emitting unit 400 disposed in the display panel 000 after passing through the film layer structures in the display panel 000. Similarly, part of the light emitted from the second light-emitting unit 400 is blocked by the second light-absorbing layer B2, so that the light emitted from the second light-emitting unit 400 is not emitted out from a side of the first light-emitting unit 300 disposed in the display panel 000 after passing through the film layer structures in the display panel 000. In this way, only the light emitted from the first light-emitting unit 300 is emitted out from the side of the first light-emitting unit 300 disposed in the display panel 000, and the light emitted from the second light-emitting unit 400 is not emitted out from the side of the first light-emitting unit 300; and only the light emitted from the second light-emitting unit 400 is emitted out from the side of the second light-emitting unit 400 disposed in the display panel 000, and the light emitted from the first light-emitting unit 300 is not emitted out from the side of the second light-emitting unit 400. Thus, the display panel 000 has a better effect when performing double-sided display.

It should be noted that the first light-absorbing layer B1 and the second light-absorbing layer B2 both refer to film layers having a relatively high light absorption rate, for example, the first light-absorbing layer B1 and the second light-absorbing layer B2 are black light-absorbing. Here, the first light-absorbing layer B1 and the second light-absorbing layer B2 have a light absorption rate higher than 90%.

In summary, the display panel provided in the embodiments of the present disclosure includes a base, a driving layer, a first light-emitting unit and a second light-emitting unit. A plurality of first light-emitting unit arranged in an array are provided on the side of the base away from the driving layer, and under the condition that each of the first light-emitting units emits light, a corresponding image can be displayed on the side of the base away from the driving layer. A plurality of second light-emitting unit arranged in an array are provided on the side of the driving layer away from the base, and under the condition that each of the second light-emitting units emits light, a corresponding image can be displayed on the side of the driving layer away from the base. Therefore, the display panel not only can display images on one side by means of the first light-emitting units, but also can display images on the other side by means of the second light-emitting units, and the display panel can perform a double-sided display without the backlight module and the two liquid crystal display panels used in combination. In addition, the first driving structure of the driving layer in the display panel can drive the first light-emitting unit to emit light independently, and the second driving structure of the driving layer can drive the second light-emitting unit to emit light independently. Therefore, clear display images can be presented on both sides of the display panel without having to make each light-emitting unit emit light with high brightness. In this way, the power consumption of the display panel can be effectively reduced.

The embodiments of the present disclosure further provide a method for manufacturing a display panel, and the method is applicable for manufacturing the display panel in the above embodiments. The method includes: forming a driving layer, a first light-emitting unit and a second light-emitting unit on a base.

The driving layer is disposed on a side of the base, and the driving layer includes a first driving structure and a second driving structure; the first light-emitting unit is disposed on the side of the base away from the driving layer and is electrically connected to the first driving structure; and the second light-emitting unit is disposed on the side of the driving layer away from the base and is electrically connected to the second driving structure.

In summary, according to the method for manufacturing the display panel provided in the embodiments of the present disclosure, by forming a plurality of first light-emitting units arranged in an array on the side of the base away from the driving layer, under the condition that each of the first light-emitting units emits light, a corresponding image can be displayed on the side of the base away from the driving layer; and by forming a plurality of second light-emitting units arranged in an array on the side of the driving layer away from the base, under the condition that each of the second light-emitting units emits light, a corresponding image can be displayed on the side of the driving layer away from the base. Therefore, the display panel not only can display images on one side by means of the first light-emitting units, but also can display images on the other side by means of the second light-emitting units, and the display panel can perform a double-sided display without the backlight module and the two liquid crystal display panels used in combination. In addition, the first driving structure of the driving layer in the display panel can drive the first light-emitting unit to emit light independently, and the second driving structure of the driving layer can drive the second light-emitting unit to emit light independently. Therefore, clear display images can be presented on both sides of the display panel without having to make each light-emitting unit emit light with high brightness. In this way, the power consumption of the display panel can be effectively reduced.

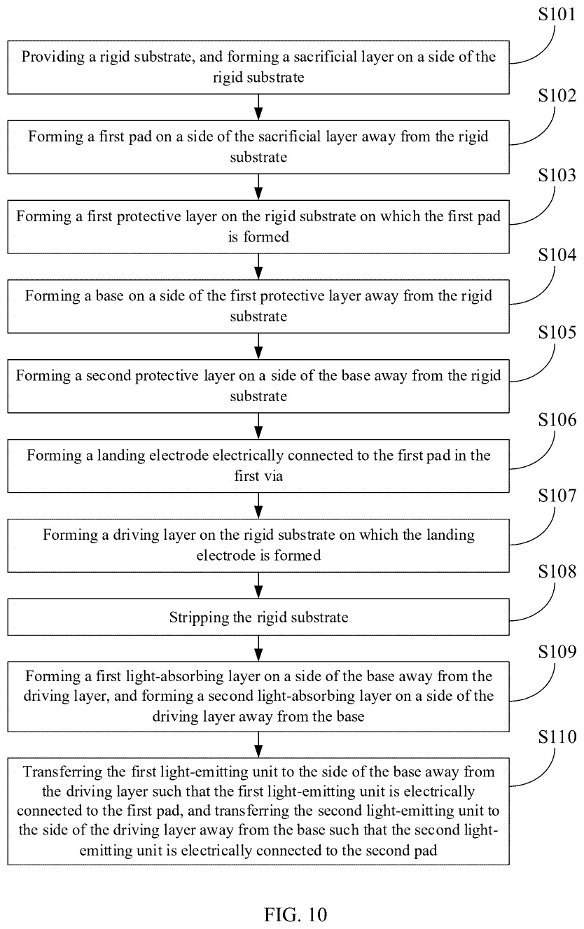

Referring to FIG. 10, FIG. 10 is a flowchart of a method for manufacturing a display panel according to some embodiments of the present disclosure. The method for manufacturing the display panel is applicable for manufacturing the display panel shown in FIG. 4, FIG. 5, or FIG. 7. The method includes the following steps.

In step S101, a rigid substrate is provided, and a sacrificial layer is formed on a side of the rigid substrate.

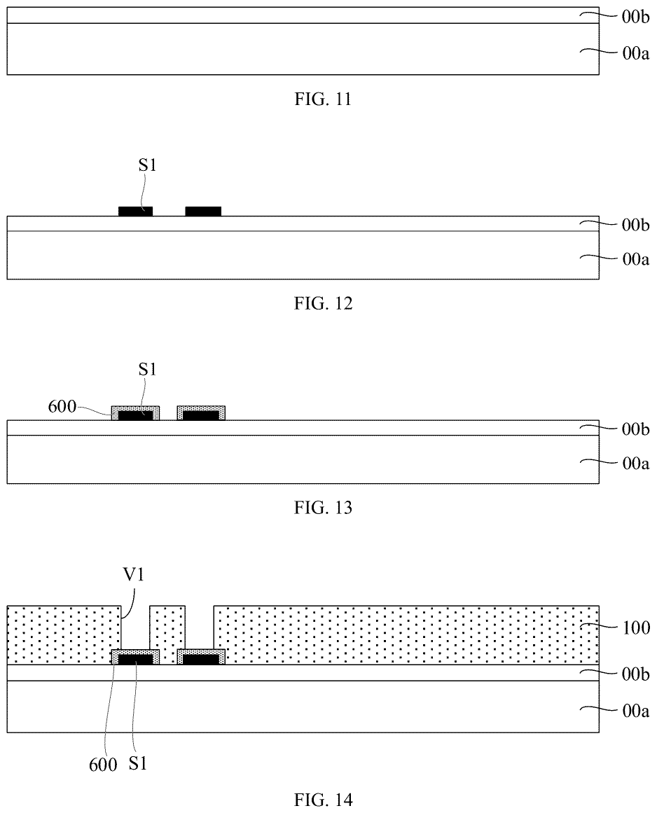

In some embodiments, the rigid substrate is a glass substrate. For example, referring to FIG. 11, FIG. 11 is a schematic diagram of forming a sacrificial layer on a side of a rigid substrate according to some embodiments of the present disclosure. The sacrificial layer 00b is formed on a side of the rigid substrate 00a by any one of deposition, coating, sputtering, or the like. The sacrificial layer is made of a material with reduced adhesion under irradiation of lasers.

In step S102, a first pad is formed on a side of the sacrificial layer away from the rigid substrate.

In some embodiments, the first pad is made of a metal material. For example, the first pad is made of a metal material such as metal copper, metal titanium, metal molybdenum, or an alloy. The thickness of the first pad ranges from 3000 angstroms to 6000 angstroms.

For example, referring to FIG. 12, FIG. 12 is a schematic diagram of forming a first pad on the side of the sacrificial layer away from the rigid substrate according to some embodiments of the present disclosure. A metal thin film is formed on the side of the sacrificial layer 00b away from the rigid substrate 00a by any one of deposition, coating, sputtering, or the like, and then the first pad S1 is formed by performing a single patterning process on the metal thin film.

In step S103, a first protective layer is formed on the rigid substrate on which the first pad is formed.

In some embodiments, the first protective layer is made of an inorganic material such as silicon nitride, silicon oxide, or silicon oxynitride. The thickness of the first protective layer ranges from 1000 angstroms to 4000 angstroms.

For example, referring to FIG. 13, FIG. 13 is a schematic diagram of forming the first protective layer on the rigid substrate on which the first pad is formed according to some embodiments of the present disclosure. An insulating thin film is formed on the rigid substrate 00a on which the first pad S1 is formed by any one of deposition, coating, sputtering or the like, and then the first protective layer 600 is formed by performing a single patterning process on the insulating thin film.

The orthographic projection of the first pad S1 on the rigid substrate 00a is within the orthographic projection of the first protective layer 600 on the rigid substrate 00a, and the first protective layer 600 covers the side surface of the first pad S1 and the side of the first pad S1 away from the rigid substrate 00a. In this way, the first protective layer 600 can protect the first pad S1, and the first protective layer 600 can isolate water and oxygen in external environment to prevent the first pad S1 from being corroded during the subsequent processes.

In step S104, a base is formed on a side of the first protective layer away from the rigid substrate.

In some embodiments, the base is made of an organic material such as polyimide (PI), polyvinyl alcohol (PVA), polyester (PET), or polyethylene naphthalate (PEN), and the thickness of the base ranges from 3 μm to 5 μm.

For example, referring to FIG. 14, FIG. 14 is a schematic diagram of forming a base on a side of the first protective layer away from the rigid substrate according to some embodiments of the present disclosure. A viscous P1 material is formed on the side of the first protective layer 600 away from the rigid substrate 00a by coating, and a high-temperature curing treatment is performed on the viscous P1 material, thereby acquiring the base 100 on the side of the first protective layer 600 away from the rigid substrate 00a. Thereafter, a single patterning process is performed on the base 100 to form a first via V1 in the base 100.

The orthographic projection of the first via V1 on the rigid substrate 00a is within the orthographic projection of the first pad S1 on the rigid substrate 00a, thereby ensuring that the landing electrode formed subsequently in the first via V1 can be normally lapped with the first pad S1.

In step S105, a second protective layer is formed on a side of the base away from the rigid substrate.

In some embodiments, the second protective layer is made of an inorganic material such as silicon nitride, silicon oxide, or silicon oxynitride. The thickness of the second protective layer ranges from 1000 angstroms to 4000 angstroms.

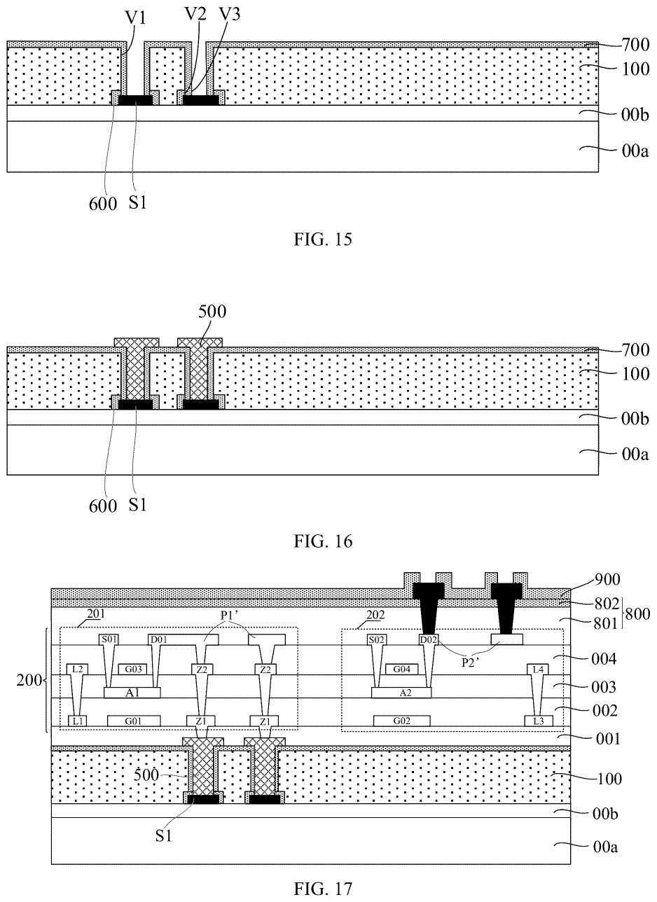

For example, referring to FIG. 15, FIG. 15 is a schematic diagram of forming a second protective layer on the side of the base away from the rigid substrate according to some embodiments of the present disclosure. The second protective layer 700 is formed on the side of the base 100 away from the rigid substrate 00a by any one of deposition, coating, sputtering, or the like, and then a single patterning process is performed on the second protective layer 700, to form a third via V3 in the second protective layer 700 and form a second via V2 in communication with the third via V3 in the first protective layer 600.

A portion of the second protective layer 700 extends into the first via V1 and covers at least a portion of the inner wall of the first via V1. The portion of the second protective layer 700 extending into the first via V1 is provided with the third via V3. The third via V3 is acquired by performing an etching process of the patterning process on the second protective layer 700. In addition, after the second protective layer 700 is etched by the etching process of the patterning process to form the third via V3 in the second protective layer 700, the first protective layer 600 is etched, thereby forming the second via V2 in communication with the third via V3 in the first protective layer 600. In this case, the orthographic projection of the second via V2 on the rigid substrate 00a is completely overlapped with the orthographic projection of the third via V3 on the rigid substrate 00a. Thus, after the landing electrode is formed in the first via V1 later, the landing electrode can sequentially pass through the third via V3 and the second via V2 to be lapped with the first pad S1.

In step S106, a landing electrode electrically connected to the first pad is formed in the first via.

For example, referring to FIG. 16, FIG. 16 is a schematic diagram of forming a landing electrode electrically connected to the first pad in the first via according to some embodiments of the present disclosure. An electroplating seed layer is formed on the side of the second protective layer 700 away from the base 100 by sputtering, and then a metal conductive layer is formed on the side of the electroplating seed layer away from the base 100 by an electroplating process. Thereafter, a single patterning process is performed on the metal thin film composed of the electroplating seed layer and the metal conductive layer that are laminated to acquire the landing electrode 500.

It should be noted that, in the process of performing the electroplating process on the metal conductive layer, the metal conductive layer fills the first via V1, so that the landing electrode 500 subsequently formed can fill up the first via V1, thereby ensuring that the portion of the landing electrode 500 disposed in the first via V1 can pass through the third via V3 and the second via V2 in sequence to be stably lapped with the first pad S1.

In step S107, a driving layer is formed on the rigid substrate on which the landing electrode is formed.

It should be noted that the driving layer may be an active driving layer as shown in FIG. 5 or a passive driving layer as shown in FIG. 7. The following embodiments are illustratively described by taking the driving layer being an active driving layer as an example.

For example, referring to FIG. 17, FIG. 17 is a schematic diagram of forming a driving layer on the rigid substrate on which the landing electrode is formed according to some embodiments of the present disclosure. A buffer layer 001, a first conductive layer, a first gate insulating layer 002, an active layer pattern, a second gate insulating layer 003, a second conductive layer, an interlayer dielectric layer 004, a third conductive layer, an insulating protective layer 800, a second pad S2 and a third protective layer 900 are sequentially formed on the side of the landing electrode 500 away from the rigid substrate 00a.

The first conductive layer includes a first gate G01, a second gate G02, a first adapter electrode Z1, a first connection electrode L1 and a third connection electrode L3. The active layer pattern includes a first active layer A1 in a first transistor and a second active layer A2 in a second transistor. The second conductive layer includes a third gate G03, a fourth gate G04, a second adapter electrode Z2, a second connection electrode L2 and a fourth connection electrode L4. The third conductive layer includes a first source S01, a first drain D01, a second source S02, a second drain DO2, a first output electrode P1′ and a second output electrode P2′. The insulating protective layer 800 includes an organic planarization layer 801 and an inorganic passivation layer 802 that are laminated. For the specific structure of the display panel, please refer to the foregoing embodiments of the structure of the display panel, and details are not described herein again.

In step S108, the rigid substrate is stripped.

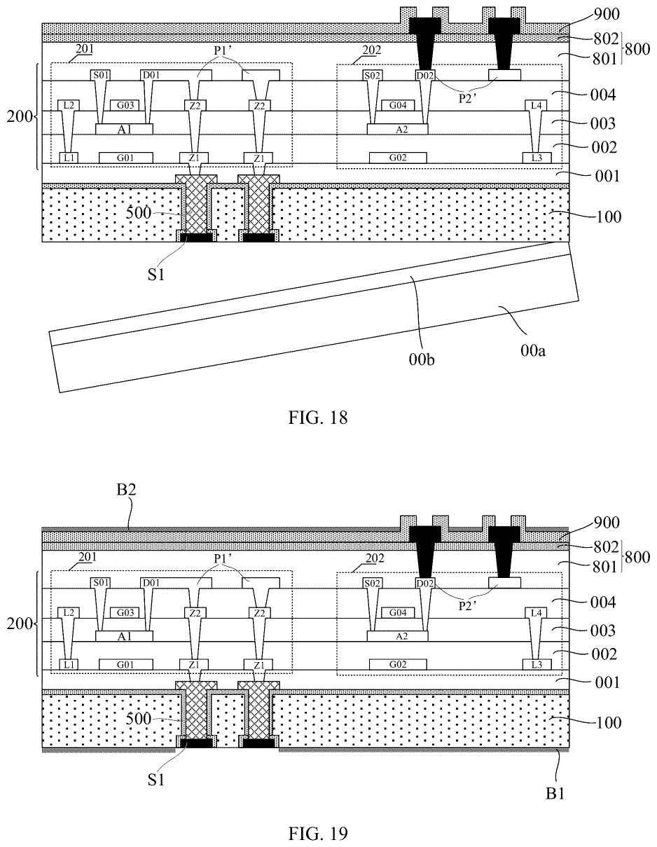

For example, referring to FIG. 18, FIG. 18 is a schematic diagram of stripping a rigid substrate according to some embodiments of the present disclosure. The sacrificial layer 00b is irradiated by lasers to reduce the viscosity of the sacrificial layer 00b, and then the rigid substrate 00a together with the sacrificial layer 00b is stripped from the base 100.

In step S109, a first light-absorbing layer is formed on a side of the base away from the driving layer, and a second light-absorbing layer is formed on a side of the driving layer away from the base.

For example, referring to FIG. 19, FIG. 19 is a schematic diagram of forming a first light-absorbing layer on the side of the base away from the driving layer and forming a second light-absorbing layer on the side of the driving layer away from the base according to some embodiments of the present disclosure. The first light-absorbing layer B1 is formed on the side of the base 100 away from the driving layer 200, and the first light-absorbing layer B1 is provided with a first opening corresponding to the first pad S1, so that the first light-emitting unit can pass through the first opening and be welded to the first pad S1 subsequently. Then, the second light-absorbing layer B2 is formed on the side of the driving layer 200 away from the base 100, and the second light-absorbing layer B2 is provided with a second opening corresponding to the second pad S2, so that the second light-emitting unit can pass through the second opening and be welded to the second pad S2 subsequently.

In step S110, the first light-emitting unit is transferred to the side of the base away from the driving layer such that the first light-emitting unit is electrically connected to the first pad, and the second light-emitting unit is transferred to the side of the driving layer away from the base such that the second light-emitting unit is electrically connected to the second pad.

For example, as shown in FIG. 5 or FIG. 7, the first light-emitting unit 300 is transferred to the side of the base 100 away from the driving layer 200, and the first light-emitting unit 300 is welded to the first pad S1. Thereafter, the second light-emitting unit 400 is transferred to the side of the driving layer 200 away from the base 100, and the second light-emitting unit 400 is welded to the second pad S2.

In summary, according to the method for manufacturing the display panel provided in the embodiments of the present disclosure, by forming a plurality of first light-emitting units arranged in an array on the side of the base away from the driving layer, under the condition that each of the first light-emitting units emits light, a corresponding image can be displayed on the side of the base away from the driving layer; and by forming a plurality of second light-emitting units arranged in an array on the side of the driving layer away from the base, under the condition that each of the second light-emitting units emits light, a corresponding image can be displayed on the side of the driving layer away from the base. Therefore, the display panel not only can display images on one side by means of the first light-emitting units, but also can display images on the other side by means of the second light-emitting units, and the display panel can perform a double-sided display without the backlight module and the two liquid crystal display panels used in combination. In addition, the first driving structure of the driving layer in the display panel can drive the first light-emitting unit to emit light independently, and the second driving structure of the driving layer can drive the second light-emitting unit to emit light independently. Therefore, clear display images can be presented on both sides of the display panel without having to make each light-emitting unit emit light with high brightness. In this way, the power consumption of the display panel can be effectively reduced.

It shall be clearly understood by those skilled in the art that, for the convenience and brevity of descriptions, for the principle of each film layer structure in the display panel described above, reference can be made to the corresponding content in the structure embodiment of the display panel, and details are not described herein again.

The embodiments of the present disclosure further provide a display device. The display device may be any product or component having a display function such as a mobile phone, a tablet computer, a television, a display, a notebook computer, a digital photo frame, a navigator, and the like. The display device includes a driving component, and the display panel in the foregoing embodiments. The driving component is electrically connected to the driving layer in the display panel, and the driving component is configured to provide a driving signal to the light-emitting unit through the driving layer.

It should be noted that in the drawings, the dimensions of layers and regions may be exaggerated for clarity of illustration. It is to be further understood that when an element or layer is referred to as being “on” another element or layer, it may be directly on other elements, or an intermediate layer may be present. Additionally, it is to be understood that when an element or layer is referred to as being “under” another element or layer, it may be directly under other elements, or more than one intermediate layer or element may be present. Additionally, it is to be understood that when a layer or element is referred to as being “between” two layers or two elements, it may be the unique layer between the two layers or two elements, or more than one intermediate layer or element may be present. Similar reference numerals indicate similar elements throughout.

In the present disclosure, the terms “first” and “second” are merely used for descriptive purposes, and shall not be construed as indicating or implying any relative importance. The term “a plurality of” refers to two or more, unless explicitly specified otherwise.

The descriptions above are merely optional embodiments of the present disclosure, and are not intended to limit the present disclosure. Within the spirit and principles of the disclosure, any modifications, equivalent substitutions, improvements, and the like are within the protection scope of the present disclosure.

1. A display panel, comprising:
a base;
a driving layer disposed on a side of the base, the driving layer comprising: a first driving structure and a second driving structure;
a first light-emitting unit disposed on a side of the base away from the driving layer and a second light-emitting unit disposed on a side of the driving layer away from the base;
wherein the first light-emitting unit is electrically connected to the first driving structure, and the second light-emitting unit is electrically connected to the second driving structure; and at least one conductive layer in the first driving structure and at least one conductive layer in the second driving structure are disposed in a same layer.

2. The display panel according to claim 1, wherein the base is provided with a first via, and the display panel further comprises: a landing electrode; wherein
at least a portion of the landing electrode is disposed in the first via, the landing electrode is electrically connected to the first driving structure, and a side of the landing electrode away from the first driving structure is electrically connected to the first light-emitting unit.

3. The display panel according to claim 2, wherein the side of the base away from the driving layer is provided with a groove in communication with the first via, and the display panel further comprises: a first pad disposed in the groove;
wherein a side of the first pad is connected to the landing electrode, and a side of the first pad away from the landing electrode is electrically connected to the first light-emitting unit.

4. The display panel according to claim 3, further comprising: a first protective layer disposed in the groove;
wherein the first protective layer is distributed between the base and the first pad, and the first protective layer is provided with a second via, and the landing electrode is electrically connected to the first pad through the second via.

5. The display panel according to claim 4, further comprising: a second protective layer disposed on a side of the base facing the driving layer, wherein a portion of the second protective layer extends into the first via and covers at least a portion of an inner wall of the first via;
wherein the portion of the second protective layer extending into the first via is provided with a third via in communication with the second via.

6. The display panel according to claim 3, wherein a side of the first pad away from the driving layer is flush with the side of the base away from the driving layer.

7. The display panel according to claim 1, wherein the first driving structure comprises a first transistor, and the second driving structure comprises a second transistor; wherein
the first transistor comprises a first active layer, and the second transistor comprises a second active layer, wherein the first active layer and the second active layer are disposed in a same layer.

8. The display panel according to claim 7, wherein the first transistor further comprises a first source and a first drain, and the second transistor further comprises a second source and a second drain; the first driving structure further comprises a first output electrode electrically connected to the first transistor, and the second driving structure further comprises a second output electrode electrically connected to the second transistor; wherein
the first source, the first drain, the second source, the second drain, the first output electrode and the second output electrode are disposed in a same layer.

9. The display panel according to claim 8, wherein
the first transistor further comprises a first gate, wherein the first gate is insulated from the first active layer, the first gate is closer to the base than the first active layer is, the first source and the first drain are lapped with the first active layer, and the first active layer is closer to the base than the first source and the first drain are;
the second transistor further comprises a second gate, wherein the second gate is insulated from the second active layer, the second gate is closer to the base than the second active layer is, the second source and the second drain are lapped with the second active layer, and the second active layer is closer to the base than the second source and the second drain are;
the display panel further comprises a first adapter electrode, wherein the first adapter electrode, the first gate and the second gate are disposed in a same layer;
wherein the first output electrode is electrically connected to the first light-emitting unit through the first adapter electrode;
optionally, wherein the first transistor further comprises a third gate, wherein the third gate is insulated from the first active layer, and the first active layer is closer to the base than the third gate is;
the second transistor further comprises a fourth gate, wherein the fourth gate is insulated from the second active layer, and the second active layer is closer to the base than the fourth gate is;
the display panel further comprises a second adapter electrode, wherein the second adapter electrode, the third gate and the fourth gate are disposed in a same layer;
wherein the first output electrode is electrically connected to the first light-emitting unit through the second adapter electrode and the first adapter electrode in sequence.

10. (canceled)

11. The display panel according to claim 8, further comprising: an insulating protective layer and a second pad that are disposed on the side of the driving layer away from the base; wherein
the insulating protective layer is provided with a fourth via corresponding to the second pad, at least a portion of the second pad extends into the fourth via and is electrically connected to the second output electrode, and a side of the second pad away from the base is electrically connected to the second light-emitting unit.

12. The display panel according to claim 11, wherein the insulating protective layer comprises an organic planarization layer and an inorganic passivation layer that are laminated, wherein
the organic planarization layer is closer to the base than the inorganic passivation layer is, the second pad comprises a portion outside the fourth via, and the portion of the second pad outside the fourth via is in contact with a side of the inorganic passivation layer away from the base.

13. The display panel according to claim 11, further comprising: a third protective layer disposed on a side of the insulating protective layer away from the base; wherein
the second pad comprises a portion outside the fourth via, and the third protective layer covers at least a portion of a side surface of the portion of the second pad outside the fourth via;
optionally, wherein a portion of the third protective layer is disposed on the side of the second pad away from the base, and the portion of the third protective layer disposed on the side of the second pad away from the base is provided with a fifth via, wherein an orthographic projection of the fifth via on a plane where the base is disposed is within an orthographic projection of the second pad on the plane where the base is disposed.

14. (canceled)

15. The display panel according to claim 11, wherein the second pad comprises a portion outside the fourth via, wherein a thickness of the portion of the second pad outside the fourth via is greater than or equal to a thickness of the third protective layer.

16. The display panel according to claim 9, wherein
the first driving structure further comprises a first connection electrode and a second connection electrode, wherein the first connection electrode is disposed in a same layer as the first gate, and the first connection electrode is electrically connected to the first gate, the second connection electrode is disposed in a same layer as the third gate, and the second connection electrode is electrically connected to the third gate, and the first connection electrode is lapped with the second connection electrode;
the second driving structure further comprises a third connection electrode and a fourth connection electrode, wherein the third connection electrode is disposed in a same layer as the second gate, the third connection electrode is electrically connected to the second gate, the fourth connection electrode is disposed in a same layer as the fourth gate, and the fourth connection electrode is electrically connected to the fourth gate, and the third connection electrode is lapped with the fourth connection electrode.

17. The display panel according to claim 1, wherein the driving layer comprises a first metal layer and a second metal layer that are laminated;
the first driving structure comprises a plurality of first driving signal lines disposed in the first metal layer and a second driving signal line disposed in the second metal layer, wherein an extending direction of the first driving signal line intersects with an extending direction of the second driving signal line;
the second driving structure comprises a plurality of third driving signal lines disposed in the first metal layer and a fourth driving signal line disposed in the second metal layer, wherein an extending direction of the third driving signal line intersects with an extending direction of the fourth driving signal line;
wherein the extending direction of the first driving signal line is parallel to the extending direction of the third driving signal line, and the extending direction of the second driving signal line is parallel to the extending direction of the fourth driving signal line.

18. The display panel according to claim 17, wherein
the plurality of first light-emitting units are arranged in an array in a plurality of rows and a plurality of columns, and the plurality of first driving signal lines comprise a plurality of groups of first driving signal lines corresponding to the plurality of columns of first light-emitting units, wherein a group of first driving signal lines is electrically connected to each of the first light-emitting units in the corresponding column of first light-emitting units, and one second driving signal line is electrically connected to each of the first light-emitting units in one row of first light-emitting units;
the plurality of second light-emitting units are arranged in an array in a plurality of rows and a plurality of columns, and the plurality of third driving signal lines comprise a plurality of groups of third driving signal lines corresponding to the plurality of columns of second light-emitting units, wherein a group of third driving signal lines is electrically connected to each of the second light-emitting units in the corresponding column of second light-emitting units, and one fourth driving signal line is electrically connected to each of the second light-emitting units in one row of second light-emitting units;
wherein the plurality of groups of first driving signal lines and the plurality of groups of third driving signal lines are alternately arranged; and the plurality of second driving signal lines and the plurality of fourth driving signal lines are alternately arranged.

19. The display panel according to claim 17, wherein a thickness of the first metal layer is greater than a thickness of the second metal layer.

20. (canceled)

21. The display panel according to claim 1, further comprising: a first light-absorbing layer disposed on the side of the base away from the driving layer and a second light-absorbing layer disposed on the side of the driving layer away from the base; wherein
the first light-emitting unit is disposed on a side of the first light-absorbing layer away from the base, and the second light-emitting unit is disposed on a side of the second light-absorbing layer away from the base.

22. The display panel according to claim 1, wherein the first light-emitting unit and the second light-emitting unit each comprise a light-emitting diode.

23. A method for manufacturing a display panel, comprising:
forming a driving layer, a first light-emitting unit and a second light-emitting unit on a base;
wherein the driving layer is disposed on a side of the base, and the driving layer comprises a first driving structure and a second driving structure; the first light-emitting unit is disposed on a side of the base away from the driving layer and is electrically connected to the first driving structure; the second light-emitting unit is disposed on a side of the driving layer away from the base and is electrically connected to the second driving structure; and at least one conductive layer in the first driving structure and at least one conductive layer in the second driving structure are disposed in a same layer.

24.-28. (canceled)
